(19) United States
(12) Patent Application Publication
(10) Pub. No.: US 2025/0318241 A1
(43) Pub. Date: Oct. 9, 2025

(54) SEMICONDUCTOR DEVICE AND METHOD FOR FABRICATING THE SAME

(71) Applicant: SK hynix Inc., Gyeonggi-do (KR)

(72) Inventors: Beom Ho MUN, Gyeonggi-do (KR); Sun Hwan HWANG, Gyeonggi-do (KR)

(21) Appl. No.: 18/827,849

(22) Filed: Sep. 9, 2024

(30) Foreign Application Priority Data
Apr. 4, 2024 (KR) 10-2024-0045850

(51) Int. Cl. H01L 29/423; H01L 29/51

(52) U.S. Cl. CPC H10D 64/513; H10D 64/681; H10D 64/693

(57) ABSTRACT

A semiconductor device includes: a trench formed in a substrate; a buried conductive layer that gap-fills a portion of the trench; and a capping structure that gap-fills a remaining portion of the trench over the buried conductive layer and includes a carbon-containing material. In the semiconductor device, junction strain may be minimized by reducing the tensile stress of a capping layer.

### CROSS-REFERENCE TO RELATED APPLICATIONS

The present application claims priority under 35 U.S.C 119(a) to Korean Patent Application No. 10-2024-0045850, filed on Apr. 4, 2024, which is incorporated herein by reference in its entirety.

### BACKGROUND

### 1. Field

Various embodiments of the present invention relate generally to semiconductor technology, and more particularly, to semiconductor devices with a buried gate structure, and methods for fabricating such devices.

### 2. Description of the Related Art

A metal gate electrode is used in a transistor for ensuring high performance of the transistor. In particular, metal gate electrodes have been proposed for controlling a threshold voltage for high-performance buried gate-type transistors. However, as semiconductor devices become more highly integrated, controlling interference between neighboring conductive lines has become a difficult issue and new solutions are needed.

### SUMMARY

Embodiments of the present invention are directed to a semiconductor device with improved electrical characteristics, and a method for fabricating the same.

Embodiments of the present invention are directed to a semiconductor device with a buried gate, and a method for fabricating the semiconductor device.

The inventive semiconductor device may exhibit improved electrical characteristics.

The inventive semiconductor device may exhibit reduced electrical interference between neighboring conductive lines.

In accordance with an embodiment of the present invention, a semiconductor device is provided. The semiconductor device may include: a trench formed in a substrate; a buried conductive layer that gap-fills a portion of the trench; and a capping structure that gap-fills a remaining portion of the trench over the buried conductive layer and includes a carbon-containing material.

In accordance with another embodiment of the present invention, a method for fabricating a semiconductor device includes: forming a trench in a substrate; forming a gate dielectric layer that covers a bottom surface and an inner surface of the trench; forming a buried conductive layer over the gate dielectric layer to gap-fill a portion of the trench; and gap-filling a remaining portion of the trench over the buried conductive layer and forming a capping structure including a carbon-containing material.

These and other features and advantages of the present invention will become apparent to those skilled in the art of the invention from the following detailed description in conjunction with the following drawings.

### BRIEF DESCRIPTION OF THE DRAWINGS

FIG. 1 is a plan view illustrating a semiconductor device in accordance with an embodiment of the present invention.

FIG. 2A is a cross-sectional view illustrating a semiconductor device taken along a line A-A′ shown in FIG. 1 in accordance with an embodiment of the present invention.

FIG. 2B is a cross-sectional view illustrating the semiconductor device taken along a line B-B′ shown in FIG. 1 in accordance with an embodiment of the present invention.

FIGS. 3 to 8 are cross-sectional views illustrating semiconductor devices in accordance with some embodiments of the present invention.

FIGS. 9 and 10 are a plan view and a cross-sectional view illustrating a semiconductor device in accordance with an embodiment of the present invention.

FIGS. 11A to 11E are process cross-sectional views illustrating a method for fabricating a semiconductor device in accordance with an embodiment of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being ‘on’ a second layer or ‘on’ a substrate, it not only refers to a case where the first layer is formed directly on the second layer or the substrate but also a case where a third layer exists between the first layer and the second layer or the substrate.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the technical concepts and scope of the present invention.

In addition, it will also be understood that when an element is referred to as being “between” two elements, it may be the only element between the two elements, or one or more intervening elements may also be present.

It should be understood that the drawings are simplified schematic illustrations of the described devices and may not include well known details to avoid obscuring the features of the invention.

It should also be noted that features present in one embodiment may be used with one or more features of another embodiment without departing from the scope of the invention.

It is further noted, that in the various drawings, like reference numbers designate like elements.

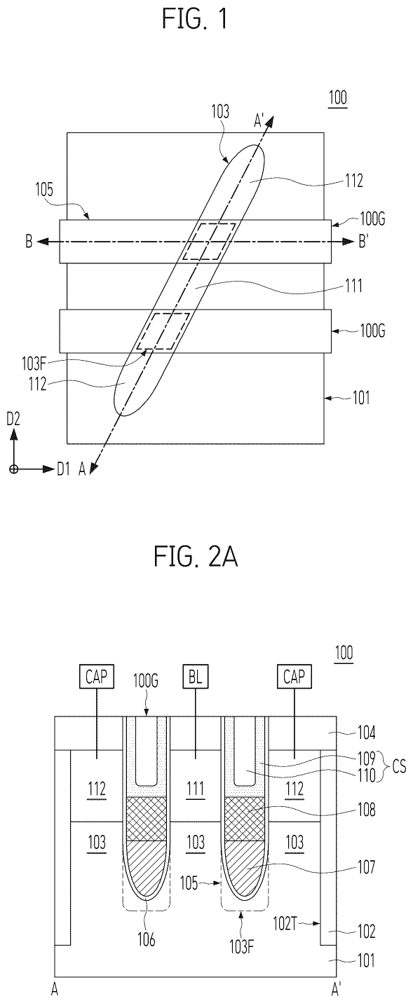

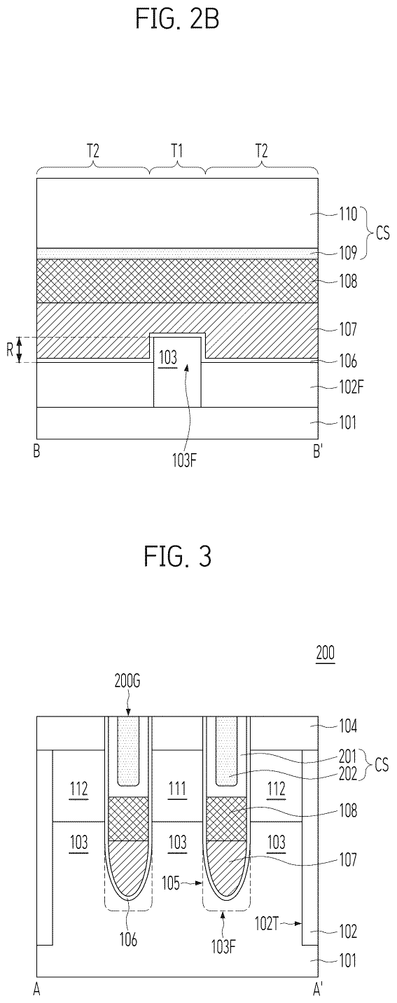

FIG. 1 is a plan view illustrating a semiconductor device in accordance with an embodiment of the present invention. FIG. 2A is a cross-sectional view illustrating a semiconductor device taken along a line A-A′ shown in FIG. 1 in accordance with an embodiment of the present invention. FIG. 2B is a cross-sectional view illustrating the semiconductor device taken along a line B-B′ shown in FIG. 1.

Referring now to FIGS. 1, 2A, and 2B, the semiconductor device 100 may include a substrate 101, a pair of buried gate structures 100G embedded in the substrate 101, a first doped region 111 disposed between the pair of the buried gate structures, and second doped regions 112. The buried gate structure 100G and the first and second doped regions 111 and 112 may form a cell transistor. The cell transistor may alleviate a short channel effect due to the buried gate structure.

The semiconductor device 100 may be part of a memory cell. For example, the semiconductor device 100 may be part of a memory cell of a Dynamic Random Access Memory (DRAM). The semiconductor device 100 may include a bit line BL and a memory storage element CAP that are electrically connected to the substrate 101. The bit line

BL may be coupled to the first doped region 111, and the memory storage element CAP may be coupled to the second doped region 112. The bit line BL and the memory storage element CAP may be disposed at a higher level than the buried gate structure 100G. The bit line BL and the memory storage element CAP may be disposed at different levels. The memory storage element CAP may be disposed at a higher level than the bit line BL. The memory storage element CAP may include a capacitor.

The substrate 101 may be a material appropriate for semiconductor processing. The substrate 101 may include a semiconductor substrate. The substrate 101 may include a material containing silicon. The substrate 101 may include silicon, single crystalline silicon, polysilicon, amorphous silicon, silicon germanium, single crystalline silicon germanium, polycrystalline silicon germanium, carbon doped silicon, a combination thereof, or a multi-layer thereof. The substrate 101 may also include other semiconductor materials such as germanium. The substrate 101 may include a group-III/V semiconductor substrate, for example, a compound semiconductor substrate such as GaAs. The substrate 101 may include a Silicon-On-Insulator (SOI) substrate.

An isolation layer 102 and active regions 103 may be formed over the substrate 101. The active regions 103 may be defined by the isolation layer 102. The active regions 103 may have a long axis and a short axis. The active regions 103 may be tilted in a diagonal direction. A pair of buried gate structures 100G disposed to be spaced apart from each other may be formed in each one of the active regions 103. A first doped region 111 may be formed in each active region 103 between the pair of the buried gate structures 100G. A second doped region 112 may be formed in each active region 103 in the outside of each buried gate structure 100G. This embodiment of the present invention may be referred to also as a ‘6F2’ structure including a pair of buried gate structures 100G, one first doped region 111, and two second doped regions 112 in one active region.

The isolation layer 102 may be a Shallow Trench Isolation (STI)

region formed by a trench etching process. The isolation layer 102 may be formed by filling a shallow trench, for example, an isolation trench 102T, with a dielectric material. The isolation layer 102 may include silicon oxide, silicon nitride, or a combination thereof.

A trench 105 may be formed in the substrate 101. The trench 105 may be formed by using hard mask layer 104 as an etch barrier and etching the substrate 101. From the perspective of a top view of FIG. 1, the trench 105 may have a line shape extending in a first direction D1. The trench 105 may be shaped like a line crossing the active region 103 and the isolation layer 102. The trenches 105 may be spaced apart in a second direction D2. The first direction D1 and the second direction D2 may be orthogonal to each other. The trench 105 may have a shallower depth than the isolation trench 102T. The lower portion of the trench 105 may have a curvature. The trench 105 may provide a space where the buried gate structure 100G is formed, and the trench 105 may be referred to as a ‘gate trench’.

According to an embodiment of the present invention, two trenches 105 may be arranged side by side in each active region 103 spaced apart from each other. Since the buried gate structure 100G provided in the inside of each trench 105 may function as a gate for a transistor, this configuration allows for the formation of two transistors in each active region 103.

The first and second doped regions 111 and 112 may be formed in each active region 103. The first and second doped regions 111 and 112 may be regions doped with a conductive dopant. For example, the conductive dopant may include phosphorus (P), arsenic (As), antimony (Sb), or boron (B). The first and second doped regions 111 and 112 may be doped with dopants of the same conductivity type. The first and second doped regions 111 and 112 may be disposed in each active region 103 on both sides of the trench 105. The first and second doped regions 111 and 112 may be spaced apart from each other by the trench 105. The bottom surfaces of the first and second doped regions 111 and 112 may be disposed at a predetermined depth from the top surface of each active region 103. The bottom surfaces of the first and second doped regions 111 and 112 may be higher than the bottom surface of the trench 105. The first doped region 111 may be referred to as a ‘first source/drain region’, and the second doped region 112 may be referred to as a ‘second source/drain region.’ A channel may be defined between the first and second doped regions 111 and 112 by the buried gate structure 100G. The channel may be defined along the profile of the trench 105.

According to an embodiment of the present invention, one first doped region 111 and a pair of second doped regions 112 may be disposed in each active region 103. The first doped region 111 may be disposed between a pair of the second doped regions 112. Hence, this configuration provides two transistors in each active region 103 which may be coupled to a common source line, that is, the same first doped region 111.

The trench 105 may include a first trench T1 and a second trench T2. The first trench T1 may be formed in the active region 103. The second trench T2 may be formed in the isolation layer 102. The trench 105 may continuously extend from the first trench T1 to the second trench T2. In the trench 105, the bottom surface of the first trench T1 may be disposed at a higher level than the bottom surface of the second trench T2. The height difference between the first trench T1 and the second trench T2 may be formed as the isolation layer 102 is recessed. Accordingly, the second trench T2 may include a recess region R whose bottom surface is lower than the bottom surface of the first trench T1. A fin 103F may be formed in the active region 103 due to the height difference between the first trench T1 and the second trench T2. Accordingly, each active region 103 may include the fin 103F.

As described above, the fin 103F may be formed below the first trench T1, and the sidewall of the fin 103F may be exposed by the recessed isolation layer 102F. The fin 103F may be a portion where a portion of a channel (not shown) is formed. The fin 103F may be called a saddle fin. The fin 103F may increase the channel width and improve the electrical characteristics.

According to another embodiment of the present invention, the fin 103F may be omitted.

The buried gate structure 100G may include a gate dielectric layer 106 that covers the bottom surface and side walls of the trench 105, and a first gate electrode 107, a second gate electrode 108 and a capping structure CS that are sequentially stacked over the gate dielectric layer 106 to fill the trench 105.

The gate dielectric layer 106 may include silicon oxide, silicon nitride, silicon oxynitride, a high-k material, or a combination thereof. The high-k material may include a material whose dielectric constant is greater than that of silicon oxide. For example, the high-k material may include a material whose dielectric constant is greater than approximately 3.9. For another example, the high-k material may include a material whose dielectric constant is greater than approximately 10. For yet another example, the high-k material may include a material having a dielectric constant of approximately 10 to 30. The high-k material may include at least one metallic element. The high-k material may include a hafnium-containing material. The hafnium-containing material may include hafnium oxide, hafnium silicon oxide, hafnium silicon oxynitride, or a combination thereof. According to another embodiment of the present invention, the high-k material may include lanthanum oxide, lanthanum aluminum oxide, zirconium oxide, zirconium silicon oxide, and zirconium silicon oxynitride, aluminum oxide, or a combination thereof. As for the high- k material, other known high-k materials may optionally be used. The gate dielectric layer 106 may include a metal oxide.

The first and second gate electrodes 107 and 108 may fill a portion of the trench 105. The first and second gate electrodes 107 and 108 may fill the lower portion of the trench 105. The first and second gate electrodes 107 and 108 may fill the lower and middle portions of the trench 105. Each of the first and second gate electrodes 107 and 108 may include at least one of a doped polysilicon material, a metal material, a metal nitride material, and a metal silicide material. For example, the metal material may include one of aluminum (Al), gold (Au), beryllium (Be), bismuth (Bi), cobalt (Co), copper (Cu), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), tellurium (Te), titanium (Ti), tungsten (W), zinc (Zn), and zirconium (Zr), or a combination thereof. For example, the metal nitride may include one of titanium nitride (TiN), tungsten nitride (WN), tantalum nitride (TaN), titanium silicon nitride (TiSiN), tantalum silicon nitride (TaSiN), and tungsten silicon nitride (WSiN) or a combination thereof. For example, the metal silicide material may be one of cobalt silicide (CoSiₓ), nickel silicide (NiSiₓ), titanium silicide (TiSiₓ), tungsten silicide (WSiₓ), and tantalum silicide (TaSiₓ), or a combination of. The first and second gate electrodes 107 and 108 may be referred to as ‘buried conductive layers’.

According to an embodiment of the present invention, the first gate electrode 107 and the second gate electrode 108 may include the same metal. According to another embodiment of the present invention, the first gate electrode 107 may include a metal-based material, and the second gate electrode 108 may include a polysilicon material.

The capping structure CS may fill the upper portion of the trench 105 over the second gate electrode 108. The capping structure CS may be formed over the second gate electrode 108 to prevent oxidation of the second gate electrode 108. Also, the capping structure CS may be formed in the trench 105 to electrically insulate the first and second gate electrodes 107 and 108 from the upper structure, such as contacts and conductive lines. According to an embodiment of the present invention, the top surface of the capping structure CS may be disposed at the same level as the top surface of the hard mask layer 104. According to another embodiment of the present invention, the top surface of the capping structure CS may be disposed at the same level as the top surface of the substrate 101.

The capping structure CS may include a carbon-containing material having a low tensile stress. The capping structure CS may include a low-k material having a low tensile stress. Here, the low-k material may include a material whose dielectric constant is lower than silicon nitride (Si₃N₄).

The capping structure CS may include a stacked structure. The capping structure CS may include a stacked structure of a first capping layer 109 and a second capping layer 110 having different stresses. The first capping layer 109 may have a cylindrical shape that covers the outer surface of the second capping layer 110. The first capping layer 109 may be conformally formed on the inner surface of the trench 105. The top surfaces of the first capping layer 109 and the second capping layer 110 may be disposed at the same level.

The first capping layer 109 and the second capping layer 110 may have the same type of stress. Alternatively, the stress values of the first and second capping layers 109 and 110 may be different from each other.

According to an embodiment of the present invention, the first capping layer 109 may have a lower tensile stress than that of the second capping layer 110. The first capping layer 109 may be a carbon-containing material having a low tensile stress. Also, the first capping layer 109 may be a low-k material having a low tensile stress. Also, the first capping layer 109 may include a material having an etch selectivity with respect to the hard mask layer 104 and the substrate 101. Also, the first capping layer 109 may include a material having excellent step coverage characteristics. The first capping layer 109 may be a compound containing Si, O, and C. For example, the first capping layer 109 may be silicon oxycarbide (SiCO). For example, the first capping layer 109 may be formed at a temperature of approximately 400° C. to 550° C. through a Chemical Vapor Deposition (CVD) process of an Inductively Coupled Plasma (ICP) method.

The second capping layer 110 may have a higher tensile stress than the first capping layer 109. For example, the second capping layer 110 may be silicon nitride. For example, the second capping layer 110 may be formed in a furnace at a temperature of approximately 550° C. or higher through a Low Pressure Chemical Vapor Deposition (LPCVD) process or an Atomic Layer Deposition (ALD) process.

The tensile stress of the first capping layer 109 may be approximately 10 times lower than the tensile stress of the second capping layer 110. For example, when the first capping layer 109 is SiCO, the tensile stress may be approximately 130 Mpa. When the second capping layer 110 is silicon nitride, the tensile stress may be approximately 1300 Mpa. The two layer capping structure CS is advantageous because, among other advantages, it allows adjusting the overall tensile stress of the capping structure CS by adjusting the thicknesses or ratios of the first and second capping layers 109 and 110, in addition to the selection of the materials used for the first and second layers of the two-layer capping structure CS.

As a comparative example, when the first capping layer 109 includes silicon oxide, the silicon oxide may be lost through a subsequent etching process (e.g., etching the hard mask layer 104 for forming a contact), thereby causing a short between the upper structure (e.g., a contact or a conductive line) and the buried gate structure 100G.

As another comparative example, when both of the first and second capping layers 109 and 110 include silicon nitride and the type of stress is adjusted differently. The silicon nitride having a compressive stress (e.g., when a Chemical Vapor Deposition (CVD) method of a Capacitively Coupled Plasma (CCP) type is applied at a temperature of less than approximately 550° C.) may have poor step coverage characteristics. Therefore, voids may occur when the trench 105 is gap-filled due to deterioration in the gap-fill characteristics and as a result, a short may occur between the upper structure (e.g., a bit line) and the buried gate structure 100G.

According to this embodiment of the present invention, the capping structure CS may include a material having excellent etch resistance and step coverage characteristics and a low tensile stress, thereby preventing a problem of a short that may occur between the buried gate structure 100G and the upper structure and alleviating a high tensile stress of silicon nitride at the same time. Also, it is possible to secure sensing margins by applying a material whose dielectric constant is lower than silicon nitride and improving the parasitic capacitance between the buried gate structure 100G and the upper structure. Also, write recovery time tWR and refresh characteristics may be improved by reducing silicon strain of a junction region, that is, the second doped region 112.

FIGS. 3 to 6 are cross-sectional views illustrating semiconductor devices in accordance with other embodiments of the present invention. The buried gate structures illustrated in FIGS. 3 to 6 may include the same constituent elements as those shown in FIG. 2A except for the capping structure. The substrate 101, the isolation layer 102, the active region 103, the hard mask layer 104, the gate dielectric layer 106, the first and second gate electrodes 107 and 108, and the first and second doped regions 111 and 112 illustrated in FIGS. 3 to 6 may include the same materials and structures as those shown in FIG. 2A.

Referring to FIG. 3, the semiconductor device 200 in accordance with an embodiment of the present invention may include a substrate 101, a pair of buried gate structures 200G embedded in the substrate 101, a first doped region 111 disposed between the pair of the buried gate structures, and second doped regions 112.

The capping structure CS may include a carbon-containing material having a low tensile stress, i.e., a material whose dielectric constant is lower than that of silicon nitride (Si₃N₄).

The capping structure CS may include a stacked structure. The capping structure CS may include a stacked structure of the first capping layer 109 and the second capping layer 110 having different stresses. The first capping layer 109 may have a cylindrical shape that covers the outer surface of the second capping layer 110. The first capping layer 109 may be conformally formed on the inner surface of the trench 105. The top surfaces of the first capping layer 109 and the second capping layer 110 may be disposed at the same level.

The first capping layer 109 and the second capping layer 110 may have the same type of stress. The stress values of the first and second capping layers 109 and 110 may be different from each other.

The first capping layer 201 of the capping structure CS in accordance with the illustrated embodiment of FIG. 3 may have a higher tensile stress than the second capping layer 202. For example, the first capping layer 201 may be silicon nitride. For example, the first capping layer 201 may be formed in a furnace at a temperature of approximately 550° C. or higher through a Low Pressure Chemical Vapor Deposition (LPCVD) process or an Atomic Layer Deposition (ALD) process. The second capping layer 202 may be a carbon-containing material having a low tensile stress. The second capping layer 202 may be a low-k material having a low tensile stress. The second capping layer 202 may include a material having an etch selectivity with respect to the hard mask layer 104 and the substrate 101. Also, the second capping layer 202 may include a material having excellent step coverage characteristics. The second capping layer 202 may be a compound containing Si, O, and C. For example, the second capping layer 202 may be silicon oxycarbide (SiCO). For example, the second capping layer 202 may be formed at a temperature of approximately 400° C. to 550° C. through a Chemical Vapor Deposition (CVD) process of an Inductively Coupled Plasma (ICP) method.

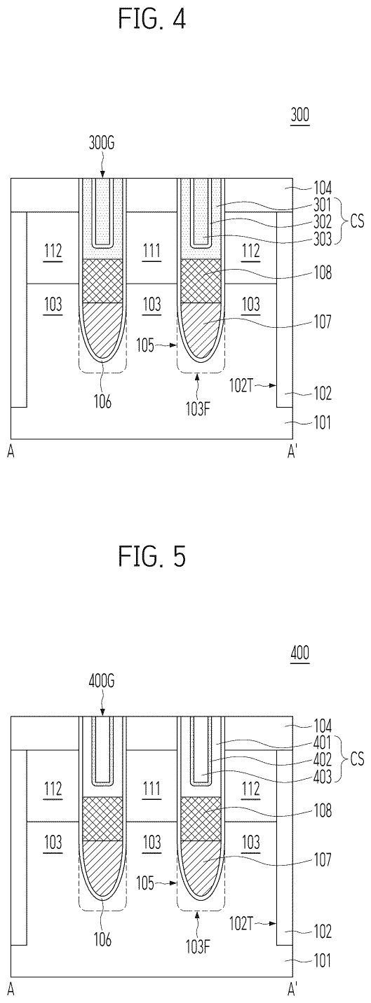

Referring to FIG. 4, the semiconductor device 300 in accordance with another embodiment of the present invention may include a substrate 101, a buried gate structure 300G embedded in the substrate 101, a first doped region 111 disposed between the pair of the buried gate structures, and second doped regions 112.

The capping structure CS in accordance with the illustrated embodiment of FIG. 4 may be a triple layer containing a carbon- containing material having a low tensile stress. The capping structure CS may include first to third capping layers 301, 302, and 303, and at least one of the first to third capping layers 301, 302, and 303 may contain a low-k material having a low tensile stress. Here, the low-k material refers to a material whose dielectric constant is lower than silicon nitride (Si₃N₄).

The capping structure CS may include a stacked structure. The capping structure CS may include a stacked structure of the first to third capping layers 301, 302, and 303 having different stresses. The first capping layer 301 may have a cylindrical shape that covers the outer surface of the second capping layer 302. The second capping layer 302 may have a cylindrical shape that covers the outer surface of the third capping layer 303. The first capping layer 301 may be conformally formed on the inner surface of the trench 105. The second capping layer 302 may be conformally formed on the inner surface of the first capping layer 301. The top surfaces of the first to third capping layers 301, 302, and 303 may be disposed at the same level.

The first to third capping layers 301, 302, and 303 may have the same type of stress. The stress values of the first to third capping layers 301, 302, and 303 may be different from each other.

According to an embodiment of the present invention, the first and third capping layers 301 and 303 may have a lower tensile stress than the second capping layer 302. The first and third capping layers 301 and 303 may include a carbon-containing material having a low tensile stress. Also, the first and third capping layers 301 and 303 may include a low-k material having a low tensile stress. Also, the first and third capping layers 301 and 303 may include a material having an etch selectivity with respect to the hard mask layer 104 and the substrate 101. Also, the first and third capping layers 301 and 303 may include a material having excellent step coverage characteristics. The first and third capping layers 301 and 303 may be a compound containing Si, O, and C. For example, the first and third capping layers 301 and 303 may be silicon oxycarbide (SiCO). For example, the first and third capping layers 301 and 303 may be formed at a temperature of approximately 400° C. to 550° C. through a Chemical Vapor Deposition (CVD) process of an Inductively Coupled Plasma (ICP) method.

The second capping layer 302 may have a higher tensile stress than the first and third capping layers 301 and 303. For example, the second capping layer 302 may be silicon nitride. For example, the second capping layer 302 may be formed in a furnace at a temperature of approximately 550° C. or higher through a Low Pressure Chemical Vapor Deposition (LPCVD) process or an Atomic Layer Deposition (ALD) process.

Referring to FIG. 5, the semiconductor device 100 in accordance with yet another embodiment of the present invention may include a substrate 101, a pair of buried gate structures 400G embedded in the substrate 101, a first doped region 111 disposed between the pair of the buried gate structures, and second doped regions 112. The capping structure CS in accordance with the embodiment of

FIG. 5 may be a triple layer containing a carbon-containing material having a low tensile stress. The capping structure CS may include first to third capping layers 401, 402, and 403, and at least one among the first to third capping layers 401, 402, and 403 may contain a low-k material having a low tensile stress. Here, the low-k material refers to a material whose dielectric constant is lower than silicon nitride (Si₃N₄).

The capping structure CS may include a stacked structure. The capping structure CS may include a stacked structure of first to third capping layers 401, 402, and 403 having different stresses. The first capping layer 401 may have a cylindrical shape that covers the outer surface of the second capping layer 402. The second capping layer 402 may have a cylindrical shape that covers the outer surface of the third capping layer 403. The first capping layer 401 may be conformally formed on the inner surface of the trench 105. The second capping layer 402 may be conformally formed on the inner surface of the first capping layer 401. The top surfaces of the first to third capping layers 401, 402, and 403 may be disposed at the same level.

The first to third capping layers 401, 402, and 403 may have the same type of stress. The stress values of the first to third capping layers 401, 402, and 403 may be different from each other.

According to an embodiment of the present invention, the second capping layer 402 may have a lower tensile stress than the first and third capping layers 401 and 403. The second capping layer 402 may be a carbon-containing material having a low tensile stress. Also, the second capping layer 402 may be a low-k material having a low tensile stress. Also, the second capping layer 402 may include a material having an etch selectivity with respect to the hard mask layer 104 and the substrate 101. Also, the second capping layer 402 may include a material having excellent step coverage characteristics. The second capping layer 402 may be a compound containing Si, O, and C. For example, the second capping layer 402 may be silicon oxycarbide (SiCO). For example, the second capping layer 402 may be formed at a temperature of approximately 400° C. to 550° C. through a Chemical Vapor Deposition (CVD) process of an Inductively Coupled Plasma (ICP) method.

The first and third capping layers 401 and 403 may have a higher tensile stress than the second capping layer 402. For example, the first and third capping layers 401 and 403 may be silicon nitride. For example, the first and third capping layers 401 and 403 may be formed in a furnace at a temperature of approximately 550° C. or higher through a Low Pressure Chemical Vapor Deposition (LPCVD) process or an Atomic Layer Deposition (ALD) process.

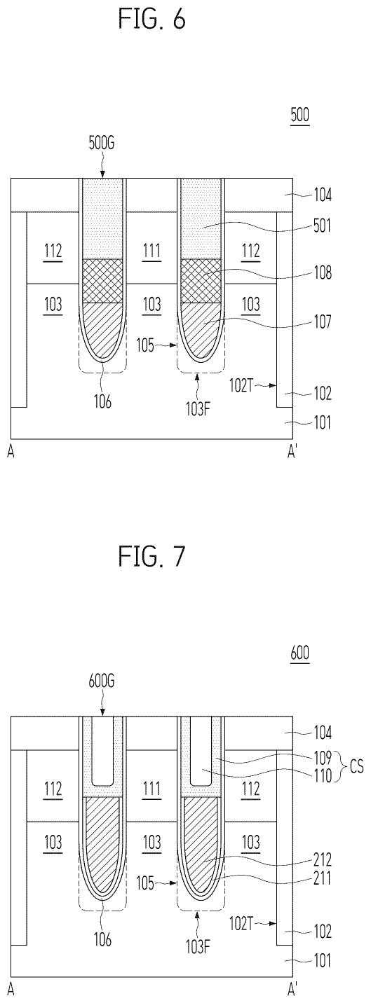

Referring to FIG. 6, the semiconductor device 500 in accordance with yet another embodiment of the present invention may include a substrate 101, a pair of buried gate structures 500G embedded in the substrate 101, a first doped region 111 disposed between the pair of the buried gate structures, and second doped regions 112.

The capping layer 501 in accordance with an embodiment of the present invention may include a single-layer structure. The capping layer 501 may be a carbon-containing material having a low tensile stress. Also, the capping layer 501 may be a low-k material having a low tensile stress. Here, the low-k material may refer to a material whose dielectric constant is lower than silicon nitride (Si₃N₄). Also, the capping layer 501 may include a material having an etch selectivity with respect to the hard mask layer 104 and the substrate 101. Also, the capping layer 501 may include a material having excellent step coverage characteristics. The capping layer 501 may be a compound containing Si, O, and C. For example, the capping layer 501 may be silicon oxycarbide (SiCO). For example, the capping layer 501 may be formed at a temperature of approximately 400° C. to 550° C. through a Chemical Vapor Deposition (CVD) process of an Inductively Coupled Plasma (ICP) method.

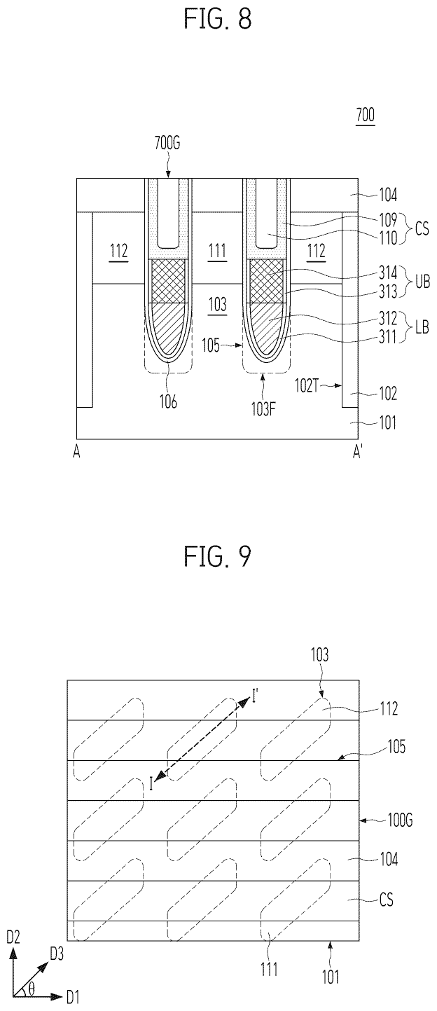

FIGS. 7 and 8 are cross-sectional views illustrating semiconductor devices in accordance with embodiments of the present invention. The buried gate structures illustrated in FIGS. 7 and 8 may include the same constituent elements as those illustrated in FIG. 2A except for the gate electrode. A substrate 101, an isolation layer 102, an active region 103, a hard mask layer 104, a gate dielectric layer 106, a capping structure CS, and first and second doped regions 111 and 112 illustrated in FIGS. 7 and 8 may include the same materials and structures as those illustrated in FIG. 2A, and a detailed description of them will be omitted.

Referring to FIG. 7, the semiconductor device 600 in accordance with yet another embodiment of the present invention may include a substrate 101, a pair of buried gate structures 600G embedded in the substrate 101, a first doped region 111 disposed between the pair of the buried gate structures, and second doped regions 112.

The buried gate structure 600G in accordance with an embodiment of the present invention may include a single-type gate electrode 212. A barrier layer 211 may be disposed between the gate electrode 212 and the gate dielectric layer 106.

The gate electrode 212 may include a low-resistance material. The gate electrode 212 may include a metal material. For example, the metal material may include one of aluminum (AI), gold (Au), beryllium (Be), bismuth (Bi), cobalt (Co), copper (Cu), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), tellurium (Te), titanium (Ti), tungsten (W), zinc (Zn), and zirconium (Zr), or a combination thereof.

The barrier layer 211 may be applied to prevent metal diffusion or adjust the work function of the gate electrode 212. The barrier layer 211 may include a metal nitride, a metal oxide, or a metal silicide. The barrier layer 211 may include a metal nitride, a metal oxide, or a metal silicide having the same metal as that of the gate electrode 212.

According to another embodiment of the present invention, the barrier layer 211 may include a metal nitride, a metal oxide, or a metal silicide having a different metal from that of the gate electrode 212.

According to another embodiment of the present invention, the capping structure CS of the buried gate structure 600G may be replaced with the capping structure CS or the capping layer 501 illustrated in FIGS. 3 to 6.

Referring to FIG. 8, the semiconductor device 700 in accordance with yet another embodiment of the present invention may include a substrate 101, a pair of buried gate structures 700G embedded in the substrate 101, a first doped region 111 disposed between the pair of the buried gate structures, and second doped regions 112.

The buried gate structure 700G in accordance with an embodiment of the present invention may include a stacked structure of a lower gate LB and an upper gate UB. The lower gate LB may include a stacked structure of a first barrier layer 311 and a first gate electrode 312. The upper gate UB may include a second barrier layer 313 and a second gate electrode 314.

The first barrier layer 311 may include a high work function material. For example, the first barrier layer 311 may include a metal nitride or a metal oxide. The first barrier layer 311 may include the same metal material as that of the first gate electrode 312. The first gate electrode 312 may include a low-resistance material. The first gate electrode 312 may include a metal material or a metal nitride. For example, the metal material may include one of aluminum (Al), gold (Au), beryllium (Be), bismuth (Bi), cobalt (Co), copper (Cu), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), tellurium (Te), titanium (Ti), tungsten (W), zinc (Zn), and zirconium (Zr), or a combination thereof.

The second barrier layer 313 may include a low work function material. The second barrier layer 313 may include a metal nitride or polysilicon. The second barrier layer 313 may include the same metal material as that of the second gate electrode 314. The second gate electrode 314 may include a low-resistance material. The second gate electrode 314 may include a metal material or a metal nitride. For example, the metal material may include one of aluminum (Al), gold (Au), beryllium (Be), bismuth (Bi), cobalt (Co), copper (Cu), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), tellurium (Te), titanium (Ti), tungsten (W), zinc (Zn), and zirconium (Zr), or a combination thereof.

According to another embodiment of the present invention, the capping structure CS of the buried gate structure 700G according to an embodiment of the present invention may be replaced with the capping structure CS or the capping layer 501 illustrated in FIGS. 3 to 6.

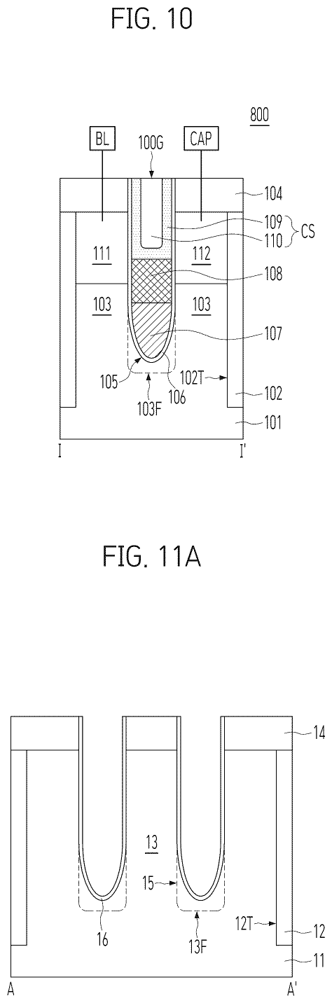

FIGS. 9 and 10 are a plan view and a cross-sectional view illustrating a semiconductor device in accordance with an embodiment of the present invention. FIG. 9 is a plan view illustrating a semiconductor device in accordance with an embodiment of the present invention. FIG. 10 is a cross-sectional view taken along a line I-I′ shown in FIG. 9.

Referring to FIGS. 9 and 10, the semiconductor device 800 in accordance with another embodiment of the present invention may include a substrate 101, a buried gate structure 100G embedded in the substrate 101, a first doped region 111, and second doped region 112. The buried gate structure 100G and the first and second doped regions 111 and 112 may form a cell transistor. The cell transistor may alleviate a short channel effect due to the buried gate structure.

The semiconductor device 800 may be part of a memory cell. For example, the semiconductor device 800 may be part of a memory cell of a DRAM. The semiconductor device 800 may include a bit line BL and a memory storage element CAP electrically connected to the substrate 101. The bit line BL may be electrically connected to the first doped region 111, and the memory storage element CAP may be electrically connected to the second doped region 112. The bit line BL and the memory storage element CAP may be disposed at a higher level than the buried gate structure 100G. The bit line BL and the memory storage element CAP may be disposed at different levels. The memory storage element CAP may be disposed at a higher level than the bit line BL. The memory storage element CAP may include a capacitor. According to another embodiment of the present invention, the memory storage element CAP may be a thyristor, a phase change material, a magnetic tunnel junction (MTJ), or a variable resistance material.

An isolation layer 102 and active regions 103 may be formed over the substrate 101. The active regions 103 may be defined by the isolation layer 102. The isolation layer 102 may be a Shallow Trench Isolation (STI) region that is formed by a trench etching process. The isolation layer 102 may be formed by filling a shallow trench, for example, an isolation trench 102T, with a dielectric material. The isolation layer 102 may include silicon oxide, silicon nitride, or a combination thereof.

The active regions 103 may be formed of strips and may be arranged as an array. The array of the active regions 103 may include a row array and/or a column array. The row array of the active regions 103 may include the active regions 103 that are arranged in the first direction D1. The column array of the active regions 103 may include the active regions 103 that are arranged in the second direction D2. The longitudinal direction of the active regions 103, that is, the third direction D3, may be non-orthogonal to the first direction D1 and the second direction D2, forming an intersection angle θ. The intersection angle θ between the first direction D1 and the third direction D3 of each active region 103 may range from approximately 10° to 80°, but the embodiments of the present invention are not limited thereto. The range of the intersection angle θ may be affected by parameters such as the area of each active region 103, the line width of the bit line, and the line width of the buried gate structure 100G. From the perspective of a top view, the cross-section of each active region 103 may be a parallelogram, for example, a parallelogram including rounded edges.

The active regions 103 may be arranged in a unidirection of the third direction D3.

A trench 105 may be formed in the substrate 101. The trench 105 may be formed by using the hard mask layer 104 as an etch barrier and etching the substrate 101. From the perspective of the top view of FIG. 1, the trench 105 may have a line shape extending in the first direction D1. The trench 105 may be shaped like a line crossing the active regions 103 and the isolation layer 102. One trench 105 may be formed in each active region 103.

The trenches 105 may be spaced apart from each other in the second direction D2. The trenches 105 may have a shallower depth than the isolation trench 102T. The lower portion of the trenches 105 may have a curvature. Each trench 105 may provide a space where the buried gate structure 100G is formed. The trench 105 may be referred to as a ‘gate trench 105’.

A fin 103F may be formed below the trench 105. The fin 103F may be formed by additionally etching the bottom surface of the trench 105 of the isolation layer 102 to create a height difference between the bottom surface of the trench 105 of the active region 103 and the bottom surface of the trench 105 of the isolation layer 102. The fin 103F may be called a saddle fin. The fin 103F may increase the channel width and improve the electrical characteristics.

According to another embodiment of the present invention, the fin 103F may be omitted.

A first doped region 111 and a second doped region 112 may be formed in the active region 103. The first doped region 111 may be formed in the active region 103 on one side of the buried gate structure 100G, and the second doped region 112 may be formed in the active region 103 on the other side of the buried gate structure 100G.

The first and second doped regions 111 and 112 may be regions doped with a conductive dopant, such as, for example, phosphorus (P), arsenic (As), antimony (Sb), or boron (B). The first and second doped regions 111 and 112 may be doped with dopants of the same conductivity type. The first and second doped regions 111 and 112 may be disposed in the active regions 103 on both sides of the trench 105. Each pair of first and second doped regions 111 and 112 may be spaced apart from one of the trenches 105. The bottom surfaces of the first and second doped regions 111 and 112 may be disposed at a predetermined depth from the top surface of the active region 103. The bottom surfaces of the first and second doped regions 111 and 112 may be higher than the bottom surface of the trench 105. The first doped region 111 may be referred to as a ‘first source/drain region 111’, and the second doped region 112 may be referred to as a ‘second source/drain region 112’. A channel may be defined between the first and second doped regions 111 and 112 by the buried gate structure 100G. The channel may be defined along the profile of the trench 105.

The buried gate structure 100G may be embedded in the trench 105. The buried gate structure 100G may be disposed in the active region 103 between the first and second doped regions 111 and 112 and extend into the isolation layer 102. In the buried gate structure 100G, the bottom surface of the portion disposed in the active region 103 and the bottom surface of the portion disposed in the isolation layer 102 may be disposed at different levels. When the fin region 103F is omitted, the buried gate structure 100G may have the bottom surface of the portion disposed in the active region 103 and the bottom surface of the portion disposed in the isolation layer 102 disposed at the same level.

The buried gate structure 100G may be embedded in the trench 105. The buried gate structure 100G may include the same structure as the buried gate structure 100G illustrated in FIG. 2A.

According to another embodiment of the present invention, the buried gate structure 100G may include the same structure as those of the buried gate structures in accordance with the embodiments of the present invention illustrated in FIGS. 3 to 8.

According to FIGS. 1, 2A, and 2B the semiconductor device 100 may include a plurality of memory cells, and the neighboring memory cells may be separated from each other by the isolation layer 102. One memory cell may be formed over one active region 103, and this may be referred to as a ‘memory cell of a 1G1A (one gate-one active) structure.’ In the memory cell of the 1G1A structure, the bit line BL may be coupled to one active region 103, so one memory cell may be coupled to one bit line BL. The memory cell of the 1G1A structure may include 1T1C (one transistor-one capacitor). As a comparative example, in a typical DRAM, two memory cells may be formed in one active region, and two gate electrodes may be formed in one active region, and two neighboring memory cells may share one bit line.

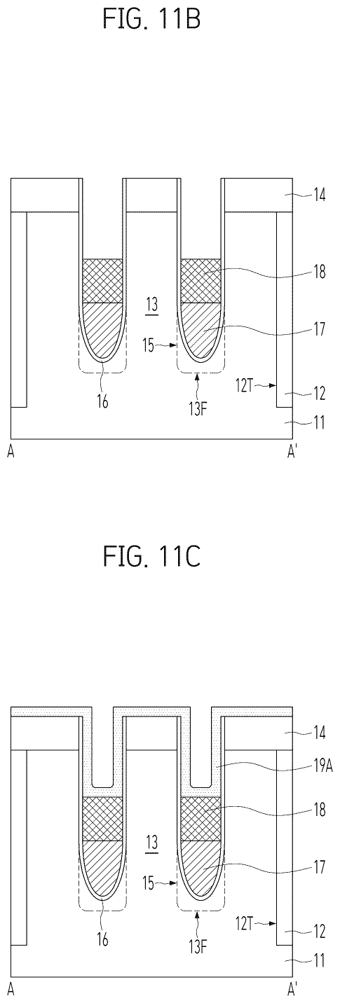

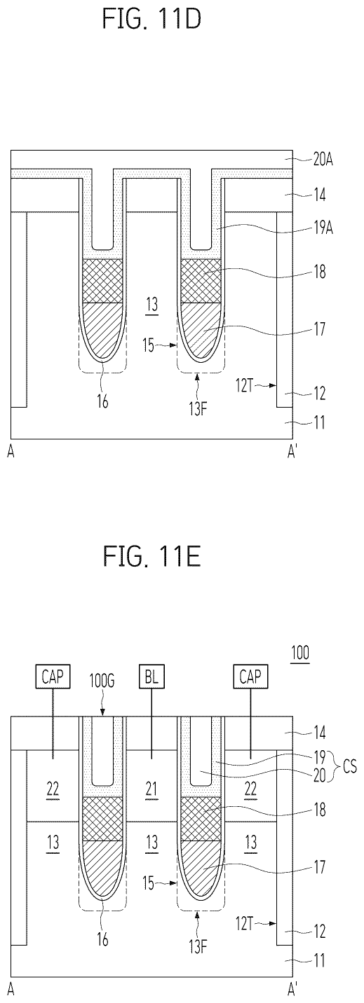

FIGS. 11A to 11E are process cross-sectional views illustrating a method for fabricating a semiconductor device in accordance with an embodiment of the present invention illustrated in FIGS. 1, 2A and 2B.

Referring to FIG. 11A, an isolation layer 12 may be formed over the substrate 11 and may define active region 13. The isolation layer 12 may be formed by a Shallow Trench Isolation (STI) process. For example, an isolation trench 12T may be formed by etching the substrate 11. The isolation trench 12T may be filled with a dielectric material, thereby forming the isolation layer 12. The isolation layer 12 may include silicon oxide, silicon nitride, or a combination thereof. A Chemical Vapor Deposition (CVD) process or another deposition process may be used to fill the isolation trench 12T with a dielectric material. A planarization process such as a Chemical Mechanical Polishing (CMP) process may be additionally used.

A trench 15 may be formed in the substrate 11. The trench 15 may be formed in the shape of a line crossing the active region 13 and the isolation layer 12. The trench 15 may be formed by a process of using the hard mask layer 14 as an etch mask and etching the substrate 11. The hard mask layer 14 may be formed over the substrate 11 and may have a line-shaped opening. The hard mask layer 14 may be formed of a material having an etch selectivity with respect to the substrate 11. The hard mask layer 14 may be a silicon oxide, such as TEOS (Tetra-Ethyl-Ortho-Silicate). The trench 15 may be formed to be shallower than the isolation trench 12T. The depth of the trench 15 may be sufficient to increase the average cross-sectional area of the subsequent gate electrode. Accordingly, the resistance of the gate electrode may be reduced. The bottom edge of the trench 15 may have a curvature.

Subsequently, the fin region 13F may be formed. To form the fin region 13F, the isolation layer 12 below the trench 15 may be selectively recessed. The structure of the fin region 13F may be like the fin region 103F of FIG. 2B.

Subsequently, a gate dielectric layer 16 may be formed conformally on the surface of the trench 15. Before the gate dielectric layer 16 is formed, etch damage on the surface of the trench 15 may be recovered. For example, after a sacrificial oxide is formed through a thermal oxidation treatment, the sacrificial oxide may be removed.

The gate dielectric layer 16 may be formed through a thermal oxidation process. The gate dielectric layer 16 may include silicon oxide.

According to another embodiment of the present invention, the gate dielectric layer 16 may be formed by a Chemical Vapor Deposition (CVD) process or an Atomic Layer Deposition (ALD) process. The gate dielectric layer 16 formed by a deposition process may include a high-k material, an oxide, a nitride, an oxynitride, or a combination thereof. The high-k material may include a hafnium-containing material. The hafnium-containing material may include hafnium oxide, hafnium silicon oxide, hafnium silicon oxynitride, or a combination thereof. According to another embodiment of the present invention, the high-k material may include lanthanum oxide, lanthanum aluminum oxide, zirconium oxide, zirconium silicon oxide, zirconium silicon oxynitride, aluminum oxide, or a combination thereof. As for the high-k material, other known high-k materials may optionally be used. The gate dielectric layer 16 may include a material having a high oxygen atom planar density.

Referring to FIG. 11B, first and second gate electrodes 17 and 18 may be formed sequentially over the gate dielectric layer 16.

The first gate electrode 17 may be formed by a series of processes of forming a first conductive material to fill the trench 15 over the gate dielectric layer 16 and performing a recessing process onto the first conductive material. The recessing process may be performed by a dry etching process, for example, an etch-back process.

Subsequently, the second gate electrode 18 may be formed by a series of processes of forming a second conductive material to fill the trench 15 over the first gate electrode 17, and then performing a recessing process onto the second conductive material. The recessing process may be performed by a dry etching process, for example, an etch-back process.

Each of the first and second gate electrodes 17 and 18 may include at least one of a doped polysilicon material, a metal material, a metal nitride material, and a metal silicide material. For example, the metal material may include one of aluminum (Al), gold (Au), beryllium (Be), bismuth (Bi), cobalt (Co), copper (Cu), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), tellurium (Te), titanium (Ti), tungsten (W), zinc (Zn), and zirconium (Zr), or a combination thereof. For example, the metal nitride may include one of titanium nitride (TIN), tungsten nitride (WN), tantalum nitride (TaN), titanium silicon nitride (TiSiN), tantalum silicon nitride (TaSiN), and tungsten silicon nitride (WSiN), or a combination thereof. For example, the metal silicide material may be one of cobalt silicide (CoSiₓ), nickel silicide (NiSiₓ), titanium silicide (TiSiₓ), tungsten silicide (WSiₓ), and tantalum silicide (TaSiₓ), or a combination thereof.

According to an embodiment of the present invention, the first gate electrode 17 and the second gate electrode 18 may include the same metal. According to another embodiment of the present invention, the first gate electrode 17 may include a metal-based material, and the second gate electrode 18 may include a polysilicon material.

Referring to FIG. 11C, first capping material 19A may be conformally formed over the second gate electrode 18 along the inner surface of the trench 15 and the surface of the hard mask layer 14. The first capping material 19A may include a material having excellent etch resistance and step coverage characteristics. The first capping material 19A may be a material having an etch selectivity with respect to the hard mask layer 14. The first capping material 19A may include a carbon-containing material having a low stress. Also, the first capping material 19A may include a low-k material. Here, the low-k material may refer to a material whose dielectric constant is lower than silicon nitride (Si₃N₄).

The first capping material 19A may be a compound containing Si, O, and C. For example, the first capping material 19A may be silicon oxycarbide (SiCO). For example, the first capping material 19A may be formed at a temperature of approximately 400° C. to 550° C. by a Chemical Vapor Deposition (CVD) process of an Inductively Coupled Plasma (ICP) method.

Referring to FIG. 11D, a second capping material 20A may be formed over the first capping material 19A to gap-fill the remaining portion of the trench 15. The second capping material 20A may have a stress that is different from that of the first capping material 19A. The second capping material 20A may have a high tensile stress. For example, the second capping material 20A may be silicon nitride. For example, the second capping material 20A may be formed in a furnace at a temperature of approximately 550° C. or higher through a Low Pressure Chemical Vapor Deposition (LPCVD) process or an Atomic Layer Deposition (ALD) process.

Referring to FIG. 11E, a capping structure CS may be formed to gap-fill the remaining portion of the trench 15. To form the capping structure CS, the first and second capping materials 19A and 20A may be etched. The first and second capping materials 19A and 20A may be etched to expose the surface of the hard mask layer 14. Here, the etching process may be performed through a planarization process, such as, for example, a Chemical Mechanical Polishing (CMP) process or an etch back process.

Subsequently, the first and second doped regions 21 and 22 may be formed in the substrate 11, that is, the active region 13, by implanting impurity ions.

This embodiment of the present invention illustrates the method for fabricating a semiconductor device in accordance with the first embodiment illustrated in FIG. 2A, but the embodiments of the present invention are not limited thereto, and the semiconductor devices in accordance with the embodiments of the present invention illustrated in FIGS. 3 to 10 may also be fabricated through a process similar to the processes of FIGS. 11A to 11E.

According to an embodiment of the present invention, junction strain may be minimized by reducing the tensile stress of a capping layer.

According to an embodiment of the present invention, the parasitic capacitance between devices may be reduced by applying a low-k material having a low tensile stress as a capping layer.

According to an embodiment of the present invention, the reliability of semiconductor devices may be secured by alleviating the high tensile stress of silicon nitride.

While embodiments of the present invention have been described with respect to specific embodiments, it will be apparent to those skilled in the art that various changes and modifications may be made without departing from the technical concepts and scope of the Invention as defined in the following claims. Furthermore, the embodiments may be combined to form additional embodiments.

What is claimed is:

1. A semiconductor device comprising:
a trench formed in a substrate;
a buried conductive layer filling a lower portion of the trench; and
a capping structure over the buried conductive layer in the trench,
wherein the capping structure includes a carbon-containing material.

2. The semiconductor device of claim 1, wherein the capping structure includes first and second capping layers.

3. The semiconductor device of claim 2, wherein the first capping layer is conformally formed along inner walls of the buried conductive layer and the trench, and
the first capping layer covers a bottom surface and an outer wall of the second capping layer.

4. The semiconductor device of claim 2, wherein the first capping layer has a lower tensile stress than the second capping layer.

5. The semiconductor device of claim 4, wherein the first capping layer includes a carbon-containing material, and
the second capping layer includes silicon nitride.

6. The semiconductor device of claim 2, wherein the capping structure further includes a third capping layer over the second capping layer, and
the second capping layer covers a bottom surface and an outer wall of the third capping layer.

7. The semiconductor device of claim 6, wherein the third capping layer includes a carbon-containing material or silicon nitride.

8. The semiconductor device of claim 2, wherein the second capping layer has a lower tensile stress than the first capping layer.

9. The semiconductor device of claim 8, wherein the first capping layer includes silicon nitride, and
the second capping layer includes a carbon-containing material.

10. The semiconductor device of claim 1, wherein the capping structure is formed of a single layer.

11. The semiconductor device of claim 1, wherein the carbon-containing material includes a low-k material.

12. The semiconductor device of claim 1, wherein the carbon-containing material includes a compound containing Si, O, and C.

13. The semiconductor device of claim 1, wherein the carbon-containing material includes silicon oxycarbide (SiCO).

14. The semiconductor device of claim 1, further comprising:
first and second doped regions in the substrate on both sides of the trench.

15. The semiconductor device of claim 1, further comprising:
a gate dielectric layer between the buried conductive layer and the trench.

16. The semiconductor device of claim 1, wherein the substrate includes a plurality of active regions that are spaced apart from each other, and
a pair of trenches are spaced apart from each other in each active region.

17. The semiconductor device of claim 1, wherein the substrate includes a plurality of active regions spaced apart from each other, and
one trench is disposed in each active region.
